(19) United States
(12) Patent Application Publication
(10) Pub. No.: US 2009/0325359 A1
(43) Pub. Date: Dec. 31, 2009

(54) INTEGRATED CIRCUIT SYSTEM EMPLOYING A MODIFIED ISOLATION STRUCTURE

(75) Inventors: Huang Liu, Singapore (SG); Johnny Widodo, Singapore (SG); Jeff Shu, Singapore (SG); Luona Goh Loh Nah, Singapore (SG); Jack Cheng, Singapore (SG); Wei Lu, Singapore (SG); Jingze Tian, Singapore (SG); Xuesong Rao, Singapore (SG)

Correspondence Address: LAW OFFICES OF MIKIO ISHIMARU, 333 W. EL CAMINO REAL, SUITE 330, SUNNYVALE, CA, 94087, US

(73) Assignee: CHARTERED SEMICONDUCTOR MANUFACTURING LTD., Singapore (SG)

(21) Appl. No.: 12/165,624

(22) Filed: Jun. 30, 2008

(51) Int. Cl. H01L 21/762

(52) U.S. Cl. 438/424; 257/E21.549

(57) ABSTRACT

An integrated circuit system that includes: providing a substrate; forming a trench within the substrate; forming a liner on a sidewall of the trench; and forming a dielectric material at a trench bottom with a dielectric width dimension that exceeds that of a width dimension of the trench.

### TECHNICAL FIELD

The present invention relates generally to integrated circuits, and more particularly to an integrated circuit system employing a modified isolation structure.

### BACKGROUND ART

Integrated circuits are used in many portable electronic products, such as cell phones, portable computers, voice recorders, etc. as well as in many larger electronic systems, such as cars, planes, industrial control systems, etc. Integrated circuits may include a combination of active devices, passive devices and their interconnections.

The continuing trend within the semiconductor industry is to form these integrated circuits on semiconductor substrates that have increasingly higher device densities and smaller device feature sizes (i.e., smaller critical dimensions). Unfortunately, this continued shrinkage and increased density for integrated circuits brings with it new problems. Notably, one such fundamental problem is the ability to provide an efficient and reliable process that adequately separates adjacent integrated circuits.

Some of the most frequently used methods for electrically isolating one region of a substrate from another include local oxidation of silicon (LOCOS) and shallow trench isolation. The shallow trench isolation technique has received particular notice as it provides a small isolation region, while providing a level substrate surface. Unfortunately, the conventional deposition method for fabricating shallow trench isolations with high aspect ratios requires multiple deposition and etching cycles and, thus, it is expensive and offers reduced yield. Additionally, as the density of integrated circuits increases and element size is reduced, the gap-fill deposition methods tend to provide inadequate step coverage resulting in incompletely filled trenches, which can result in detrimental isolation and further reduced yields. These prior attempts have produced additional fabrication cycles, additional costs, reduced performance and reduced yields.

However, despite these problems, adequate insulation or isolation among individual elements still must be achieved in order to ensure optimal performance of the current and future technology nodes for integrated circuit systems.

Thus, a need still remains for a reliable integrated circuit system and method of fabrication, wherein the integrated circuit system exhibits improved electrical isolation among integrated circuit elements. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including: providing a substrate; forming a trench within the substrate; forming a liner on a sidewall of the trench; and forming a dielectric material at a trench bottom with a dielectric width dimension that exceeds that of a width dimension of the trench.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a partial cross sectional view of an integrated circuit system in an initial stage of manufacture in accordance with an embodiment of the present invention;

FIG. 2 is the structure of FIG. 1 after forming and patterning a mask layer;

FIG. 3 is the structure of FIG. 2 after etching;

FIG. 4 is the structure of FIG. 3 after forming a liner;

FIG. 5 is the structure of FIG. 4 after an optional etching process that increases the size of a trench bottom;

FIG. 6 is the structure of FIG. 4 or 5 after formation of a dielectric material;

FIG. 7 is the structure of FIG. 6 after removing the liner;

FIG. 8 is the structure of FIG. 7 after etching a protective layer;

FIG. 9 is the structure of FIG. 8 after formation of a dielectric liner;

FIG. 10 is the structure of FIG. 9 after deposition of a fill material; and

FIG. 11 is a flow chart of an integrated circuit system for an integrated circuit system in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown exaggerated in the drawing FIGS. Additionally, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “processing” as used herein includes deposition of material or photoresist, patterning, exposure, development, etching, cleaning, and/or removal of the material or photoresist as required in forming a described structure.

The term “on” is used herein to mean there is direct contact among elements.

The terms “example” or “exemplary” are used herein to mean serving as an instance or illustration. Any aspect or embodiment described herein as an “example” or as “exemplary” is not necessarily to be construed as preferred or advantageous over other aspects or designs.

The terms “first”, “second”, and “third” as used herein are for purposes of differentiation between elements only and are not to be construed as limiting the scope of the present invention.

The term “layer” encompasses both the singular and the plural unless otherwise indicated.

The term “system” as used herein means and refers to the method and to the apparatus of the present invention in accordance with the context in which the term is used.

Generally, the following embodiments relate to the formation of an integrated circuit system including a strategically engineered isolation structure that can help to reduce well-to-well leakage and improve electrical isolation between adjacent active and/or passive devices.

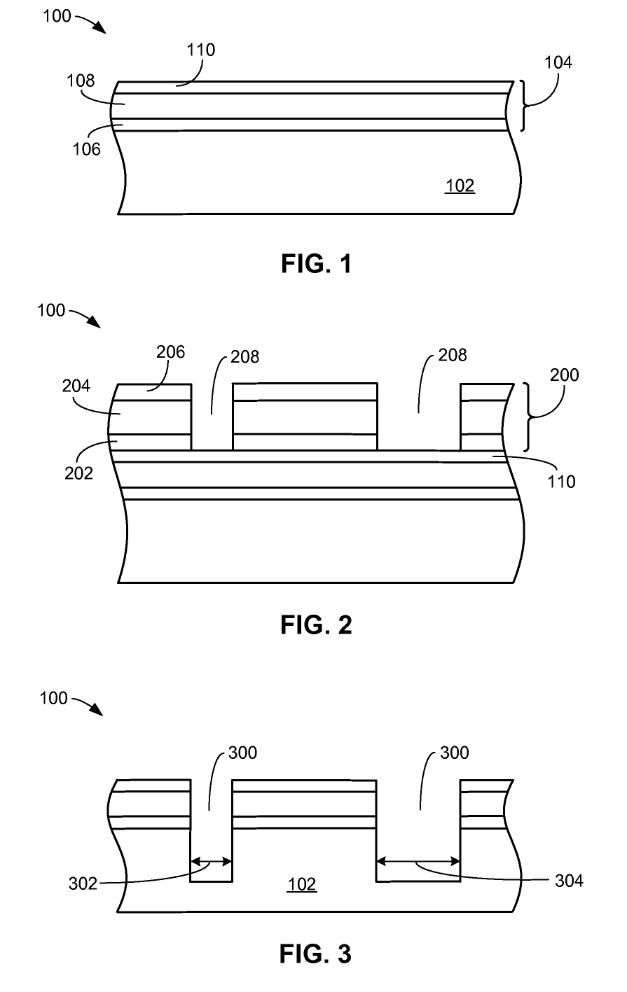

FIGS. 1-10, which follow, depict by way of example and not by limitation, an exemplary process flow for the formation of a substrate within an integrated circuit system and they are not to be construed as limiting. It is to be understood that a plurality of conventional processes that are well known within the art and not repeated herein, may precede or follow FIGS. 1-10. Moreover, it is to be understood that many modifications, additions, and/or omissions may be made to the below described process without departing from the scope of the claimed subject matter. For example, the below described process may include more, fewer, or other steps.

Additionally, it is to be appreciated that the integrated circuit system of the present disclosure may include any number of multi-electrode devices in which the current flowing between two specified electrodes is controlled or modulated by the voltage applied at a control electrode. Exemplary illustrations may include an n-channel field effect transistor (NFET), a p-channel field effect transistor (PFET), a complementary metal-oxide-silicon (CMOS) configuration, a single-gate transistor, a multi-gate transistor, a fin-FET, or an annular gate transistor. Furthermore, it is to be understood that one or more of the integrated circuit system could be prepared at one time on a medium, which could be separated into individual or multiple integrated circuit assemblies at a later stage of fabrication.

Moreover, it is to be understood that the integrated circuit system manufactured by the embodiments described herein can be used within processor components, memory components, logic components, digital components, analog components, mixed-signal components, power components, radio-frequency (RF) components (e.g., RF CMOS circuits), digital signal processor components, micro-electromechanical components, optical sensor components, and so forth, in numerous configurations and arrangements as may be needed.

Referring now to FIG. 1, therein is shown a partial cross sectional view of an integrated circuit system 100 in an initial stage of manufacture in accordance with an embodiment of the present invention.

In some embodiments, the integrated circuit system 100 may include a substrate 102, such as a two hundred (200) mm or three hundred (300) mm semiconductor wafer upon which any number of active and/or passive device structures and their interconnections could be formed. In such cases, a multitude of different regions (e.g., memory, logic, etc.) can be formed over, on and/or within the substrate 102 for the manufacture of active and/or passive device structures by conventional deposition, patterning, photolithography, and etching techniques known in the semiconductor processing industry.

In general, the substrate 102 may include any semiconducting material, such as, Si, SiC, SiGe, Si/SiGe, SiGeC, Ge, GaAs, InAs, InP, other III/V or II/VI compound semiconductors, as well as silicon-on-insulator configurations. Additionally, the substrate 102 may also include doped and undoped configurations, epitaxial layers, strained configurations, and one or more crystalline orientations (e.g., <100>, <110>, and/or <111> orientations), which may be strategically employed to optimize carrier mobility within NFET and/or PFET devices. The substrate 102 may also include any material that becomes amorphous upon implantation.

In some embodiments, the substrate 102 may possess a thickness ranging from about one hundred (100) nanometers to about several hundred microns, for example.

However, the examples provided for the substrate 102 are not to be construed as limiting and the composition of the substrate 102 may include any surface, material, configuration, or thickness that physically and electrically enables the formation of active and/or passive device structures.

Additionally, prior to forming any subsequent layers over the substrate 102, it is to be understood that the substrate 102 may undergo a cleaning step to remove surface contaminants, such as particles, mobile ionic contaminants, organics and native oxides.

The integrated circuit system 100 may also include a protective layer 104 formed over or on the substrate 102. In some embodiments, the protective layer 104 may include a first dielectric layer 106, a second dielectric layer 108, and a third dielectric layer 110.

Generally, the first dielectric layer 106 can be formed over or on the substrate 102. In some embodiments, the first dielectric layer 106 can be formed over or on the entirety of the integrated circuit system 100, and in other embodiments the first dielectric layer 106 can be formed over or on selected portions of the integrated circuit system 100. Generally, the first dielectric layer 106 may include any material that helps to protect the substrate 102 during subsequent processing and/or helps to reduce stress between the substrate 102 and subsequently deposited layers thereover.

The first dielectric layer 106 can be made from dielectric materials such as an oxide, a nitride, or a combination thereof, but preferably includes silicon dioxide. The first dielectric layer 106 can be formed by a variety of techniques, including, but not limited to, chemical vapor deposition, physical vapor deposition and thermal oxidation.

In some embodiments, the first dielectric layer 106 may include a thin barrier layer of thermal oxide (e.g., silicon dioxide), commonly termed a pad oxide within the semiconductor industry. However, it is to be understood that the type of materials and method chosen for the formation of the first dielectric layer 106 is not limited to the above example and may include any material and method that helps to protect the substrate 102 during subsequent processing and/or helps to reduce stress between the substrate 102 and subsequently deposited layers thereover.

Generally, the first dielectric layer 106 may include a thickness ranging from about 20 angstroms to about 200 angstroms. However, it is to be understood that the thickness of the first dielectric layer 106 may be smaller or larger and may vary with the design specifications of the integrated circuit system 100.

The second dielectric layer 108 can be formed over or on the first dielectric layer 106. In some embodiments, the second dielectric layer 108 can be formed over or on the entirety of the integrated circuit system 100, and in other embodiments the second dielectric layer 108 can be formed over or on selected portions of the integrated circuit system 100. Generally, the second dielectric layer 108 may include any material that helps to protect the substrate 102 during subsequent processing and/or any material that possesses an etch selectivity with respect to the first dielectric layer 106.

The second dielectric layer 108 can be made from dielectric materials such as an oxide, a nitride, or a combination thereof, but preferably includes silicon nitride. The second dielectric layer 108 can be formed by a variety of techniques, including, but not limited to, chemical vapor deposition, physical vapor deposition and thermal oxidation.

In some embodiments, the second dielectric layer 108 may include a mask material (e.g., silicon nitride), commonly termed a hard mask within the semiconductor industry. However, it is to be understood that the type of materials and method chosen for the formation of the second dielectric layer 108 is not limited to the above example and may include any material and method that helps to protect the substrate 102 during subsequent processing and/or any material that possesses an etch selectivity with respect to the first dielectric layer 106.

Generally, the second dielectric layer 108 may include a thickness ranging from about 200 angstroms to about 2000 angstroms. However, it is to be understood that the thickness of the second dielectric layer 108 may be smaller or larger and may vary with the design specifications of the integrated circuit system 100.

The integrated circuit system 100 may also include the third dielectric layer 110 formed over or on the second dielectric layer 108. In some embodiments, the third dielectric layer 110 can be formed over or on the entirety of the integrated circuit system 100, and in other embodiments the third dielectric layer 110 can be formed over or on selected portions of the integrated circuit system 100. Generally, the third dielectric layer 110 may include any material that helps to protect the substrate 102 during subsequent processing and/or any material that possesses an etch selectivity with respect to the second dielectric layer 108.

The third dielectric layer 110 can be made from dielectric materials such as an oxide, a nitride, or a combination thereof, but preferably includes silicon dioxide. The third dielectric layer 110 can be formed by a variety of techniques, including, but not limited to, chemical vapor deposition, physical vapor deposition and thermal oxidation.

In some embodiments, the third dielectric layer 110 may include a thin barrier layer of thermal oxide (e.g., silicon dioxide), commonly termed a pad oxide within the semiconductor industry. However, it is to be understood that the type of materials and method chosen for the formation of the third dielectric layer 110 is not limited to the above example and may include any material and method that helps to protect the substrate 102 during subsequent processing and/or any material that possesses an etch selectivity with respect to the second dielectric layer 108.

Generally, the third dielectric layer 110 may include a thickness ranging from about 20 angstroms to about 200 angstroms. However, it is to be understood that the thickness of the third dielectric layer 110 may be smaller or larger and may vary with the design specifications of the integrated circuit system 100.

Referring now to FIG. 2, therein is shown the structure of FIG. 1 after forming and patterning a mask layer 200. In some embodiments, the mask layer 200 may include a first layer 202, a second layer 204, and a third layer 206. The mask layer 200 can be formed over the entirety or on selected portions of the integrated circuit system 100.

Generally, the first layer 202 can be formed over or on the third dielectric layer 110. In some embodiments, the first layer 202 may include one or more layers, wherein at least one of the layers includes an anti-reflective layer, such as an organic or an inorganic dielectric material that can suppress unintended energy/light reflection from underlying layers. In such cases, the first layer 202 may include a bottom anti-reflective coating, for example. Generally, the first layer 202 may include one or more thin film layers of different material applied in a selected sequence.

It will be appreciated by those skilled in the art that the application of the first layer 202 can improve the sidewall angle (e.g., create a vertical sidewall) of an opening 208 within the mask layer 200, thereby improving critical dimension control.

In other embodiments, the first layer 202 may also include a release layer or a primer formed between the third dielectric layer 110 and an anti-reflective layer and/or a subsequently deposited masking layer, to facilitate removal of either.

The second layer 204 can be formed over or on the first layer 202. In some embodiments, the second layer 204 can be a positive or negative photoresist material that is patterned to form the opening 208. In such cases, the second layer 204 can be deposited and patterned by using materials and techniques well known within the semiconductor processing arts. Generally, the thickness of the second layer 204 can vary between about 200 nanometers and about 2000 nanometers. However, larger or smaller thicknesses of the second layer 204 may be appropriate depending on the design specifications of the integrated circuit system 100.

It will be appreciated by those skilled in the art that the thickness range for the second layer 204 is compatible with sub 65 nanometer technology where the lateral and vertical geometries of the integrated circuit system 100 are greatly reduced. The present inventors have discovered that by maintaining the second layer 204 thickness below about 2000 nanometers that critical dimension control of sub 65 nanometers devices can be improved.

The third layer 206 can be formed over or on the second layer 204. In some embodiments, the third layer 206 may include one or more layers, wherein at least one of the layers includes an anti-reflective layer that can suppress unintended energy/light reflection from underlying layers. In such cases, the third layer 206 may include a top anti-reflective coating that acts as a transparent thin-film interface layer, which uses destructive interference between light rays to eliminate reflectance. Generally, the third layer 206 may include one or more thin film layers of different material applied in a selected sequence.

It will be appreciated by those skilled in the art that the application of the third layer 206 can improve the sidewall angle (e.g., create a vertical sidewall) of the opening 208 within the mask layer 200, thereby improving critical dimension control.

Additionally, it is to be understood that each of the opening 208 can be formed where subsequent isolation structures are desired within the integrated circuit system 100. Furthermore, it will be appreciated by those skilled in the art that the size (e.g., width) of each of the opening 208 can vary depending upon its placement within the integrated circuit system 100, wherein larger forms of the opening 208 can be formed in areas of relatively less device density and smaller forms of the opening 208 can be formed in areas of relatively greater device density. Moreover, although the present embodiment depicts two of the opening 208, it is to be understood that any number of the opening 208 may be formed depending on the design specifications of the integrated circuit system 100.

Referring now to FIG. 3, therein is shown the structure of FIG. 2 after etching. Generally, each of the opening 208 within the mask layer 200, both of FIG. 2, can be transferred to the substrate 102 to form a trench 300 within the substrate 102. By way of example, the trench 300 can be formed by a multitude of etching processes including, but not limited to, wet etching and/or dry etching process techniques.

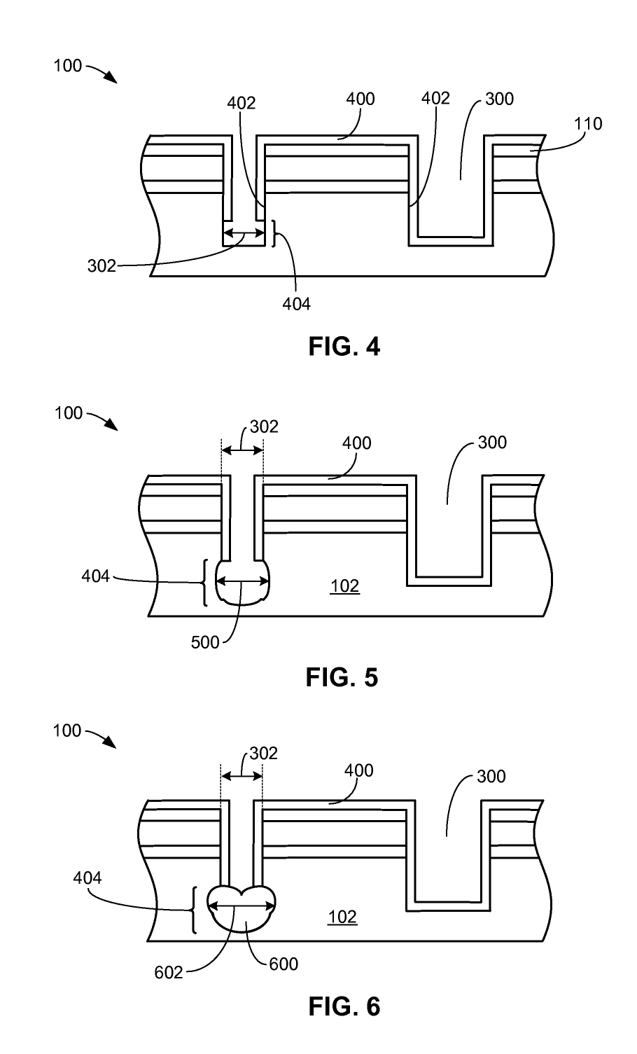

In an embodiment, some of the trench 300 can be formed with a smaller width relative to other of the trench 300. Generally, the width of each of the trench 300 depends upon the circuit design of the integrated circuit system 100, and the width of each of the trench 300 determines conformal and non-conformal step coverage of a subsequent dielectric blocking layer (e.g., a liner 400, of FIG. 4) within each of the trench 300. For example, below a certain width, the dielectric blocking layer can be controllably deposited so as to not form on a bottom portion of the trench 300, thereby leaving that bottom portion of the trench 300 exposed to a subsequent dielectric formation process. Conversely, above a certain width, the dielectric blocking layer can be controllably deposited to form on a bottom portion of the trench 300, thereby preventing exposure of the bottom portion of the trench 300 to a subsequent dielectric formation process. Accordingly, the present inventors have discovered a system and method for strategically manipulating a dielectric formation within the substrate 102 that can help to reduce well-to-well leakage and improve electrical isolation between adjacent active and/or passive devices.

It will be appreciated by those skilled in the art that below a certain critical width dimension that gap-fill of a shallow trench isolation structure becomes problematic for existing gap-fill technologies and that the bottom of the shallow trench isolation structure may merge, which can lead to poor isolation and high leakage currents between adjacent active and/or passive devices.

With this in mind, the present inventors have discovered that if some of the trench 300 are formed with a first width dimension 302 of less than about 100 nanometers that non-conformal step coverage within the trench 300 can be strategically exploited, thereby permitting a bottom portion of the trench to be exposed to a subsequent dielectric deposition or formation process. On the other hand, the present inventors have also discovered that if the trench 300 can be formed with a second width dimension 304 that is greater than 100 nanometers, then conformal step coverage may occur within the trench 300, thereby preventing exposure of the bottom portion of the trench 300 to a subsequent dielectric formation process (i.e., the bottom portion of the trench 300 is covered by the dielectric blocking layer).

It will be appreciated by those skilled in the art that a shallow trench isolation structure (e.g., the trench 300) with a width exceeding a specified critical dimension (e.g., 100 nanometers), may not require special gap-filling techniques and can be filled by existing gap-fill technology. Moreover, it will be appreciated by those skilled in the art that a shallow trench isolation structure with a width exceeding 100 nanometers, for example, will probably possess a bottom width dimension that is large enough to provide good isolation and low leakage current between adjacent active and/or passive devices.

In other embodiments, the aspect ratio of the trench 300 can be used to determine conformal and non-conformal step coverage of the subsequent dielectric blocking layer within each of the trench 300. For example, if the trench 300 with the first width dimension 302 possesses an aspect ratio in excess of 4.5:1, then non-conformal step coverage may be needed within the trench 300, thereby allowing a bottom portion of the trench to be exposed to a subsequent dielectric deposition process. Conversely, if the trench 300 with the second width dimension 304 possesses an aspect ratio less than 4.5:1, then conformal step coverage may occur within the trench 300, thereby preventing exposure of the bottom portion of the trench 300 to a subsequent dielectric formation process.

However, although the present embodiment depicts forming the trench 300 with different widths, it is to be understood that the present embodiments described herein do not require this and each of the trench 300 can be formed with a width that is approximately the same size in some embodiments.

Generally, the depth of each of the trench 300 can vary between about 5% to about 95% of the thickness of the substrate 102 or it can vary accordingly with the electrical isolation requirements for the particular technology node or circuit design of the integrated circuit system 100. In some embodiments, the depth of each of the trench 300 can vary between about 300 nanometers to about 5000 nanometers, for example. It will be appreciated by those skilled in the art that each of the trench 300 can possess a depth that is substantially uniform throughout the integrated circuit system 100 or a depth that is non-uniform throughout the integrated circuit system 100.

Subsequent to forming the trench 300, the mask layer 200, of FIG. 2, can be removed by processes well known within the art and not repeated herein.

Referring now to FIG. 4, therein is shown the structure of FIG. 3 after forming the liner 400. Generally, the liner 400 can be formed over or on the third dielectric layer 110 and within each of the trench 300, wherein each of the trench 300 are completely lined and/or partially lined. It is to be understood that the liner 400 can be formed over or on the entirety of the integrated circuit system 100 or it can be formed over or on selected portions of the integrated circuit system 100.

Generally, the liner 400 may include any material that helps to prevent subsequent dielectric formation (e.g., a dielectric blocking layer). By utilizing a material that helps to prevent subsequent dielectric formation, the present inventors have discovered a system and method that permits selective dielectric growth within strategically designed forms of the trench 300 (e.g., forms of the trench 300 with the first width dimension 302). As such, portions of the trench 300 not covered by the liner 400 can be subject to a subsequent dielectric growth that can enlarge a bottom portion of the trench 300 in excess of the first width dimension 302, thereby permitting enhanced isolation and reduced well to well leakage due to its increased size.

The liner 400 can be formed by a variety of techniques, including, but not limited to, chemical vapor deposition and physical vapor deposition, but is preferably formed by an atomic layer deposition (ALD) process. By way of example, an ALD process can permit strategic control of the deposition of the liner 400, thereby achieving conformal step coverage within some of the trench 300, while permitting non-conformal step coverage within other of the trench 300.

It will be appreciated by those skilled in the art that the coverage depth within each of the trench 300 (e.g., along a sidewall 402) can be controlled by, for example, the time of each ALD pulse. For example, a longer ALD pulse time will cover more of the sidewall 402 within the trench 300 (i.e., the liner 400 will deposit deeper within the trench 300), while a shorter ALD pulse will cover less of the sidewall 402 within the trench 300 (i.e., the liner 400 will not travel as deep within the trench 300). Additionally, it will also be appreciated by those skilled in the art that the thickness of the liner 400 deposited (e.g., within the trench 300) can be determined by the number of ALD cycles (e.g., more ALD cycles permits a thicker form of the liner 400).

Thus, by manipulating the ALD pulse time and the number of ALD pulse cycles, the depth and thickness of the liner 400 can be controlled within each of the trench 300. For example, by strategically manipulating the ALD pulse times, a controllable deposition process for the liner 400 can be achieved that permits the liner 400 to be deposited over or on between about 10% to about 90% of the sidewall 402 within designated forms of the trench 300 (e.g., forms of the trench 300 possessing the first width dimension 302). By covering between about 10% to about 90% of the sidewall 402, a trench bottom 404 can be left exposed for physical and/or chemical reaction with a subsequently deposited dielectric. In some embodiments, the percentage of the sidewall 402 covered by the liner 400 can vary or depend upon the depth of the trench 300.

Although the present embodiment discusses manipulation of ALD pulse times and the number of ALD cycles, it is to be understood that the system and method of the present embodiments are not limited to manipulation of these variables only, and those skilled in the art will appreciate that additional variables and/or parameters may also be employed/manipulated to effectuate the purpose of controlling the deposition of the liner 400 within the trench 300.

In some embodiments, the liner 400 may include a silicon nitride layer. In other embodiments, the liner 400 may include an aluminum oxide (Al₂O₃) layer. By way of example, an aluminum oxide layer can provide an effective material for the liner 400 because subsequently deposited dielectrics cannot penetrate the material due to its density. However, it is to be understood that the type of materials and method chosen for the formation of the liner 400 is not limited to the above examples and may include any material and method that helps to selectively prevent subsequent dielectric formation.

Generally, the liner 400 may include a thickness ranging from about 20 angstroms to about 200 angstroms. However, it is to be understood that the thickness of the liner 400 may be smaller or larger and may vary with the design specifications of the integrated circuit system 100 (e.g., the first width dimension 302).

Referring now to FIG. 5, therein is shown the structure of FIG. 4 after an optional etching process that increases the size of the trench bottom 404. By way of example, the trench bottom 404 can be etched by a multitude of processes including, but not limited to, wet etching and/or dry etching process techniques. In some embodiments, the etch process used to etch the trench bottom 404 can be selective to the material of the substrate 102 exposed at the bottom of some of the trench 300 (e.g., the portion not covered by the liner 400). In other embodiments, the etch process used to etch the trench bottom 404 could be a dry etch process selective to silicon. In yet other embodiments, the etch process used to etch the trench bottom 404 could be a buffered hydrofluoric etch or a hydrofluoric etch if the trench bottom 404 has been exposed to a previous oxide formation process.

Regardless of the type of etchant or etch process used, the selected etchant or etch process need only remove the material at the trench bottom 404 not covered by the liner 400, thereby increasing the surface area of the trench bottom 404, while minimizing damage to other portions of the integrated circuit system 100. By increasing the surface area of the trench bottom 404, a subsequent dielectric deposition process can form a dielectric region that is relatively larger than a dielectric region formed at the trench bottom 404 without the above described enlarging etch. It will be appreciated by those skilled in the art that a relatively larger dielectric region formed at the trench bottom 404, due to the enlarging etch described above, could provide a longer isolation path for a leakage current between adjacent structures and/or devices.

It is to be understood that the optional enlarging etch process that increases the size of the trench bottom 404 is only applied to forms of the trench 300 possessing the first width dimension 302.

Additionally, it is to be understood that after etching the trench bottom 404 that a width dimension 500 can exceed the first width dimension 302.

Referring now to FIG. 6, therein is shown the structure of FIG. 4 or 5 after formation of a dielectric material 600. Generally, the dielectric material 600 can be formed over, on or within the trench bottom 404 (e.g., the portion of the trench 300 with the first width dimension 302 not covered by the liner 400). In some embodiments, the dielectric material 600 can be formed over or on the entirety of the integrated circuit system 100, and in other embodiments the dielectric material 600 can be formed over or on selected portions of the integrated circuit system 100. Generally, the dielectric material 600 may include any material that can provide electrical isolation between adjacent structures and/or devices.

The dielectric material 600 can be made from materials such as an oxide, a nitride, or a combination thereof, but preferably includes silicon dioxide. The dielectric material 600 can be formed by a variety of techniques, including, but not limited to, thermal oxidation or thermal nitridation.

In some embodiments, the dielectric material 600 may include any type of insulating material that consumes exposed portions of the substrate 102 at the trench bottom 404 during deposition, such that a dielectric width dimension 602 exceeds that of the first width dimension 302 (e.g., due to expansion of the dielectric material 600). In other embodiments, the dielectric material 600 may include a selective thermally grown oxide (e.g., silicon dioxide), wherein the oxygen molecules diffuse in all directions within the substrate 102 during thermal oxidation. In other embodiments, the dielectric material 600 may include a selective thermally grown oxide augmented with steam annealing to help ameliorate seam formation. In yet other embodiments, the dielectric material 600 may include a selective thermally grown silicon nitride material or a silicon oxynitride material that will also expand to fill the trench bottom 404 by consuming exposed portions of the substrate 102. However, it is to be understood that the type of materials and method chosen for the formation of the dielectric material 600 is not limited to the above examples and may include any material and method that helps to provide electrical isolation between adjacent structures and/or devices.

Notably, the dielectric material 600 is only deposited within areas not covered by the liner 400. Accordingly, it has been discovered by the present inventors that a kind of inverse T-shaped trench isolation structure can be formed when the dielectric material 600 is strategically deposited to consume the material of the substrate 102 at the trench bottom 404 during formation. Moreover, it has been discovered by the present inventors that the dielectric material 600 can fill the trench bottom 404 of a high aspect ratio or relatively narrow width form of the trench 300 (e.g., forms of the trench 300 with the first width dimension 302) with minimal void formation because of the volume expansion or swelling of the dielectric material 600 during growth. Additionally, it will be appreciated by those skilled in the art that by forming the dielectric material 600 within the trench bottom 404 that the aspect ratio of the trench will be reduced, thereby easing the process requirements of a subsequent fill step.

After deposition of the dielectric material 600, it is to be understood that the dielectric width dimension 602 can be larger for the dielectric material 600 that is deposited within the trench 300 that is subject to the optional etching process used to increase the size (e.g., surface area) of the trench bottom 404.

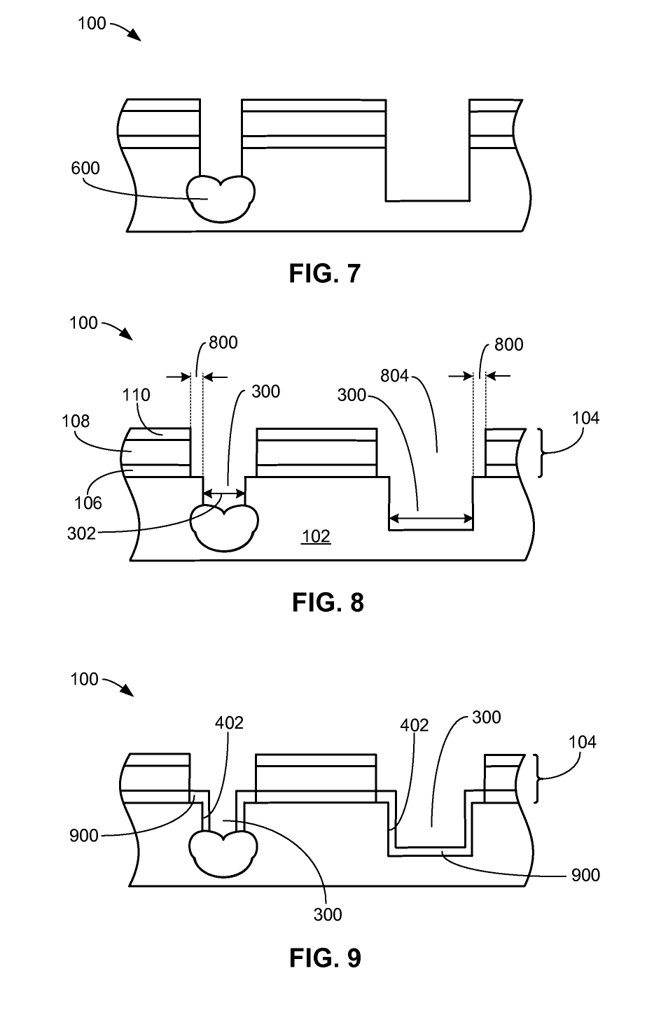

Referring now to FIG. 7, therein is shown the structure of FIG. 6 after removing the liner 400, of FIG. 6. By way of example, the liner 400 can be removed via a multitude of processes including, but not limited to, wet etching and/or dry etching process techniques. Generally, the etch process used to remove the liner 400 can be selective to the material of the liner 400. In some embodiments, the etch process used to remove the liner 400 could employ an acid based etchant, such as phosphoric acid, for example, when the dielectric material 600 is a thermally grown oxide.

However, it is to be understood that the type of etchant and/or method chosen for the removal of the liner 400 is not limited to the above examples and may include any etchant and/or method that selectively removes the liner 400, while minimizing damage to other portions of the integrated circuit system 100.

Referring now to FIG. 8, therein is shown the structure of FIG. 7 after etching the protective layer 104. By way of example, portions of the protective layer 104 can be removed via a multitude of processes including, but not limited to, wet etching and/or dry etching process techniques. Generally, the etch process used to remove portions of the protective layer 104 can be selective to the material of the first dielectric layer 106, the second dielectric layer 108, and the third dielectric layer 110. In some embodiments, the etch process used to remove the protective layer 104 could employ a reactive ion etch, for example. In other embodiments, the etch process may also include a hot phosphoric acid etch for removal of silicon nitride material within the protective layer 104.

However, it is to be understood that the type of etch process chosen for the etch back of the protective layer 104 is not limited to the above examples and may include any etch process that selectively etches back the protective layer 104, while minimizing damage to other portions of the integrated circuit system 100.

By way of example, the protective layer 104 can be etched back a distance 800 from the sidewall 402 of the trench 300. Generally, the distance 800 should be sufficient to facilitate deposition of subsequent layers within the trench 300 and/or over an exposed top surface of the substrate 102. It will be appreciated by those skilled in the art that by forming an opening 802 within the protective layer 104 that is larger than the first width dimension 302 and the second width dimension 304 that subsequent layers can be deposited within the opening 802 and within each of the trench 300 with greater ease.

In some embodiments, the distance 800 can vary between about 20 angstroms and about 200 angstroms. However, it is to be understood that the distance 800 can be smaller or larger and may vary with the design specifications of the integrated circuit system 100.

Moreover, it will be appreciated by those skilled in the art that the distance 800 need not be equal for each of the trench 300 and can vary for each of the trench 300 depending upon the design specifications of the integrated circuit system 100. For example, the trench 300 with the second width dimension 304 may not require the protective layer 104 to be etched back as far because the second width dimension 304 is sufficient to permit deposition of subsequent layers.

Referring now to FIG. 9, therein is shown the structure of FIG. 8 after formation of a dielectric liner 900. The dielectric liner 900 can be deposited over the exposed portions of the substrate 102. By way of example, the dielectric liner 900 can be deposited over or on the portion of the substrate 102 exposed by the etch back of the protective layer 104 and over or on the sidewall 402 of the trench 300.

Generally, the dielectric liner 900 can be made from any material that helps to improve the interface between the material of the substrate 102 and a subsequently deposited dielectric fill material. In some embodiments, the dielectric liner 900 may include an oxide liner deposited by thermal oxidation. In other embodiments, the dielectric liner 900 may also include silicon nitride or silicon oxynitride deposited or formed by a thermal nitridation process or a thermal oxidation process followed by an ammonia treatment.

Generally, the dielectric liner 900 may include a thickness ranging from about 10 angstroms to about 200 angstroms. However, it is to be understood that the thickness of the dielectric liner 900 may be smaller or larger and may vary with the design specifications of the integrated circuit system 100.

It will be appreciated by those skilled in the art that the exposed surfaces of the substrate 102 may undergo a cleaning step to remove surface contaminants, such as particles, mobile ionic contaminants, organics and native oxides before deposition of the dielectric liner 900.

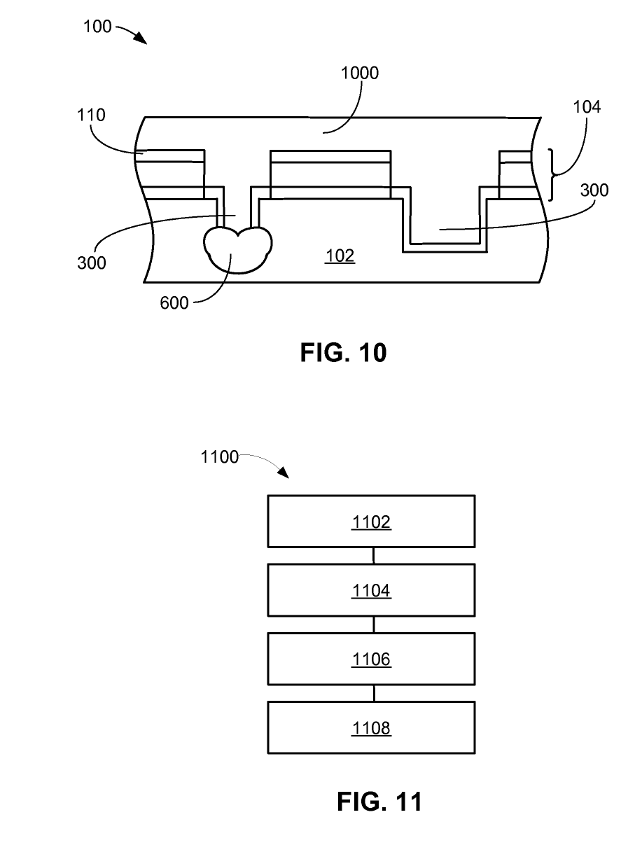

Referring now to FIG. 10, therein is shown the structure of FIG. 9 after deposition of a fill material 1000. Generally, the fill material 1000 can be formed over or on the third dielectric layer 110 and within the trench 300. In some embodiments, the fill material 1000 can be formed over or on the entirety of the integrated circuit system 100, and in other embodiments the fill material 1000 can be formed over or on selected portions of the integrated circuit system 100. Generally, the fill material 1000 may include any material that helps to provide electrical isolation between adjacent structures and/or devices.

The fill material 1000 can be made from materials such as an oxide, a nitride, or a combination thereof, but preferably includes silicon dioxide. The fill material 1000 can be formed by a variety of techniques, including, but not limited to, chemical vapor deposition, physical vapor deposition and thermal oxidation.

In some embodiments, the fill material 1000 may include an oxide material deposited by a chemical vapor deposition process. However, it is to be understood that the type of materials and method chosen for the formation of the fill material 1000 is not limited to the above example and may include any material and method that helps to provide electrical isolation between adjacent structures and/or devices.

Generally, the fill material 1000 can be deposited to a specified thickness above the surface of the third dielectric layer 110 to ensure overfilling of each of the trench 300. In some embodiments, the fill material 1000 can be deposited to a thickness of about 200 angstroms to about 2000 angstroms above the surface of the third dielectric layer 110. However, it is to be understood that the thickness of the fill material 1000 may be smaller or larger and may vary with the design specifications of the integrated circuit system 100.

It will be appreciated by those skilled in the art that after depositing the fill material 1000 that the integrated circuit system 100 can undergo additional processing steps, such as planarization and removal of the protective layer 104 before the formation of electronic devices on, over, and/or within the substrate 102 (e.g., between each of the trench 300).

It is to be understood that the trench 300 including the dielectric material 600 and/or the fill material 1000 may act as isolation structures designed to electrically isolate the electronic devices. As such, it will be appreciated by those skilled in the art that the electronic devices can be strategically designed, formed, and/or implemented to take advantage of the improved isolation and reduced well to well leakage afforded by the system and method of the present embodiments.

By way of example, the electronic devices formed on, over, and/or within the integrated circuit system 100 may include active and/or passive device structures, such as processor components, memory components, logic components, digital components, analog components, mixed-signal components, power components, radio-frequency (RF) components (e.g., RF CMOS circuits), digital signal processor components, micro-electromechanical components, optical sensor components, and so forth, in numerous configurations and arrangements as may be needed.

Referring now to FIG. 11, therein is shown a flow chart of an integrated circuit system 1100 for the integrated circuit system 100 in accordance with an embodiment of the present invention. The integrated circuit system 1100 includes providing a substrate in a block 1102; forming a trench within the substrate in a block 1104; forming a liner on a sidewall of the trench in a block 1106; and forming a dielectric material at a trench bottom with a dielectric width dimension that exceeds that of a width dimension of the trench in a block 1108.

It has been discovered that the present invention thus has numerous aspects. One such aspect is that the present invention improves isolation and reduces leakage current between adjacent devices by forming an inverse T-shaped isolation structure via a selective deposition of a dielectric material within the bottom of a trench. The additional enlarged dielectric material formed at the trench bottom in the above described unique configurations provides the additional insulation and isolation between adjacent structures.

Another aspect is that the present invention provides a system and method for increasing the distance that a carrier must travel in order to cause isolation failure because of the enlarged area occupied by the dielectric material at the trench bottom.

Another aspect is that the present invention helps to reduce the occurrence of void formations in the bottom portion of an inverse T-shaped isolation structure by utilizing a strategically deposited liner and selective deposition of an enlarging dielectric material within the trench bottom.

Another aspect is that the present invention permits the formation of an enlarged area of dielectric material at a trench bottom without complicated processing steps. By reducing the complexity of the manufacturing process, the cost of manufacturing and the costs associated with yield loss can be improved.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system of the present invention furnishes important and heretofore unknown and unavailable solutions, capabilities, and functional aspects for enhancing electrical isolation among integrated circuit elements. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

1. A method for manufacturing an integrated circuit system comprising:
providing a substrate;
forming a trench within the substrate;
forming a liner on a sidewall of the trench by non-conformal deposition; and
forming a dielectric material at a trench bottom with a dielectric width dimension that exceeds that of a width dimension of the trench.

2. The method as claimed in claim 1 wherein:
forming the liner includes depositing the liner via atomic layer deposition.

3. The method as claimed in claim 1 wherein:
forming the liner includes depositing the liner over about 10% to about 90% of the sidewall.

4. The method as claimed in claim 1 wherein:
forming the liner includes forming an aluminum oxide layer or a silicon nitride layer.

5. The method as claimed in claim 1 wherein:
forming the dielectric material includes depositing an oxide, a nitride, or a combination thereof.

6. A method for manufacturing an integrated circuit system comprising:
providing a substrate;
forming a trench within the substrate;
forming a liner on a sidewall of the trench by non-conformal deposition;
etching a trench bottom not covered by the liner; and
forming a dielectric material at the trench bottom with a dielectric width dimension that exceeds that of a first width dimension of the trench.

7. The method as claimed in claim 6 wherein:
etching the trench bottom alters the surface area of the trench bottom.

8. The method as claimed in claim 6 wherein:
etching the trench bottom alters a path for a leakage current.

9. The method as claimed in claim 6 wherein:
forming the dielectric material includes a thermal oxidation process employing steam annealing.

10. The method as claimed in claim 6 wherein:
forming the dielectric material includes forming an inverse T-shaped isolation structure.

11. A method for manufacturing an integrated circuit system comprising:
providing a substrate;
forming a trench with a first width dimension and a trench with a second width dimension within the substrate;
forming a liner on a sidewall of the trench with a first width dimension by non-conformal deposition;
forming a dielectric material at a trench bottom of the trench with a first width dimension, wherein a dielectric width dimension of the dielectric material exceeds that of the first width dimension of the trench; and
forming a fill material within each of the trenches.

12. The method as claimed in claim 11 wherein:
forming the liner includes depositing the liner via atomic layer deposition.

13. The method as claimed in claim 11 wherein:
forming the liner includes depositing the liner over about 10% to about 90% of the sidewall of the trench with the first width dimension.

14. The method as claimed in claim 11 wherein:
forming the liner includes forming an aluminum oxide layer or a silicon nitride layer.

15. The method as claimed in claim 11 wherein:
forming the dielectric material includes depositing an oxide, a nitride, or a combination thereof.

16. The method as claimed in claim 11 further comprising:
etching a trench bottom not covered by the liner before forming the dielectric material.

17. The method as claimed in claim 16 wherein:
etching the trench bottom alters the surface area of the trench bottom.

18. The method as claimed in claim 16 wherein:
etching the trench bottom alters a path for a leakage current.

19. The method as claimed in claim 11 wherein:
forming the dielectric material includes a thermal oxidation process employing steam annealing.

20. The method as claimed in claim 11 wherein:
forming the dielectric material includes forming an inverse T-shaped isolation structure.
